(19) United States
(12) Patent Application Publication
(10) Pub. No.: US 2024/0177042 A1
(43) Pub. Date: May 30, 2024

(54) Integrated Quantum Computing with Epitaxial Materials

(71) Applicant: Cornell University, Ithaca, NY (US)

(72) Inventors: Phillip Dang, Ithaca, NY (US); John Wright, Ithaca, NY (US); Guru Bahadur Singh Khalsa, Ithaca, NY (US); Huili Grace Xing, Ithaca, NY (US); Debdeep Jena, Ithaca, NY (US)

(73) Assignee: Cornell University, Ithaca, NY (US)

(21) Appl. No.: 18/277,519

(22) PCT Filed: Feb. 17, 2022
(86) PCT No.: PCT/US2022/070708

§ 371 Date: Aug. 16, 2023

Related U.S. Application Data
(60) Provisional application No. 63/150,383, filed on Feb. 17, 2021.

(51) Int. Cl. G06N 10/40; H10N 60/01; H10N 60/12; H10N 60/80; H10N 60/85

(52) U.S. Cl. CPC G06N 10/40; H10N 60/0241; H10N 60/0912; H10N 60/12; H10N 60/805; H10N 60/855

(57) ABSTRACT

Vertically integrated superconductor/semiconductor heterostructures that comprise the necessary components of a quantum computer, which could enable integrated on-chip quantum computing at millikelvin temperatures, are disclosed.

### CROSS-REFERENCE TO RELATED APPLICATIONS

This application claims priority to U.S. Provisional Patent Application No. 63/150,383 filed Feb. 17, 2021, which is incorporated herein by reference in its entirety and for all purposes.

### STATEMENT REGARDING FEDERALLY SPONSORED RESEARCH OR DEVELOPMENT

This invention was made with U.S. Government support from the Office of Naval Research under Grant No. N00014-17-1-2414. The U.S. Government has certain rights in the invention.

### BACKGROUND

These teachings relate generally to components for quantum computing, and, more particularly, to integrated components for quantum computing

Most quantum computing platforms require qubit operation at millikelvin-level temperatures. In many embodiments of a quantum computer, the components must be dispersed through multiple temperature stages ranging from 10 mK to 300 K. Due to this, the computers are several-feet-tall dilution refrigerators and contain macroscopic components. However, quantum computers would be able to greatly miniaturize, as was the case with classic computers, through the use of integrated circuits with microscopic components on a single chip that can operate at millikelvin temperatures. To realize this, there is a need for the development of integrated quantum computing circuits and material platforms that would allow such integration.

### BRIEF SUMMARY

Vertically-integrated superconductor/semiconductor heterostructures that include the necessary components of a quantum computer, which could enable quantum computing at millikelvin temperatures integrated on-chip, are disclosed herein below.

In one instantiation, the quantum computing apparatus of these teachings includes a first layer of superconductor material, a not intentionally doped metal-polar Group III nitride nucleation layer disposed over at least a portion of the layer of superconductor material, a Group III nitride buffer layer epitaxially deposited on at least a portion of the not intentionally doped metal-polar Group III nitride nucleation layer, a first Group III nitride layer epitaxially deposited on at least a portion of the Group III nitride buffer layer, and a second Group III nitride layer epitaxially deposited on the first Group III nitride layer. Materials and thickness of the first Group III nitride layer and the second Group III nitride layer are selected such that an electronic polarization discontinuity across a heterojunction between the first Group III nitride layer and the second Group III nitride layer causes formation of a 2D electron gas (2DEG) below the second Group III nitride layer. The 2DEG and superconductivity can simultaneously occur in a single nanoscale device.

In one instance, the Group III nitride buffer and the first Group III nitride layer are a same layer.

In instantiations of the quantum computing apparatus of these teachings, the apparatus also includes a second layer of superconductor material epitaxially deposited on one surface of a substrate, and a layer of insulating or semiconducting or metallic material epitaxially deposited on the second layer of superconductor material. The first layer of superconductor material is epitaxially deposited on the layer of insulating or semiconducting or metallic material. The second layer of superconductor material, the layer of insulating or semiconducting or metallic material and the first layer of superconductor material are patterned in order to obtain a number of quantum processing elements arranged in a matrix

In another instantiation, the quantum computing apparatus of these teachings includes a first layer of superconductor material epitaxially deposited on one surface of the substrate layer or on a surface of a buffer layer disposed on a substrate layer, a layer of insulating or semiconducting or metallic material epitaxially grown on the first layer of superconductor material, and a second layer of superconductor material grown on the layer of insulating or semiconducting or metallic material. The first layer of superconductor material, the layer of insulating or semiconducting or metallic material and the second layer of superconductor material are patterned in order to obtain a number of quantum processing elements. Electrically conductive material filled through substrate vias (TSVs) connect the one surface of the substrate layer or a surface of the buffer layer to an opposing surface of the substrate layer. Electronic components are disposed on the opposing surface of the substrate layer or on a third layer of superconductor material epitaxially deposited on the opposing surface of the substrate layer.

In yet another instantiation, the quantum computing apparatus of these teachings includes a number of quantum dots. Each quantum dot, from the number of quantum dots, includes one of (a) a nanocolumn structure having a Group III nitride buffer layer, a first Group III nitride layer epitaxially deposited on at least a portion of the Group III nitride buffer layer, and a second Group III nitride layer epitaxially deposited on the first Group III nitride layer, materials and thickness of the first Group III nitride layer and the second Group III nitride layer selected such that electronic polarization discontinuity across a heterojunction between the first Group III nitride layer and the second Group III nitride layer causes formation of a 2D electron gas (2DEG) below the second Group III nitride layer, or (b) a nanocolumn structure having a Group III nitride buffer layer, a self assembled Group III nitride quantum well, and a first Group III nitride layer epitaxially deposited on the self assembled Group III nitride quantum well and the Group III nitride buffer layer as a covering layer. And at least one of a superconducting stripline, superconducting transmission line, superconducting waveguide, superconducting conductor coupled to at least one of the quantum dots.

In still another instantiation, the quantum computing apparatus of these teachings includes a first layer of superconductor material epitaxially deposited on one surface of a substrate layer, a layer of insulating or semiconducting or metallic material epitaxially grown on the first layer of superconductor material, a second layer of superconductor material grown on the layer of insulating or semiconducting or metallic material, the first layer of superconductor material, the layer of insulating or semiconducting or metallic material and the second layer of superconductor material being patterned in order to obtain at least one or more quantum processing elements, a first layer of electrically conductive material deposited over a section of the one surface of the substrate layer, a first not intentionally doped AlN layer deposited over the first layer of electrically conductive material, a second layer of electrically conductive material deposited over the first not intentionally doped AlN layer, over a portion of one side of the first not intentionally doped AlN layer, and operatively connecting to one of the one or more quantum processing elements; the first not intentionally doped AlN layer, the first layer of electrically conductive material and the second layer of electrically conductive material forming a first BAW filter. The substrate layer is selected to propagate acoustic communication from the first BAW filter. A third layer of electrically conductive material is deposited over a section of an opposing surface of the substrate layer. A second not intentionally doped AlN layer is deposited over the first layer of electrically conductive material. A fourth layer of electrically conductive material is deposited over the second not intentionally doped AlN layer, over a portion of one side of the second not intentionally doped AlN layer, and operatively connecting to electronic components. The second not intentionally doped AlN layer, the third layer of electrically conductive material and the fourth layer of electrically conductive material form a second BAW filter. The second BAW filter is located at a position on the opposing surface of the substrate layer receiving acoustic communication from the first BAW filter. In one instance, the substrate is one of AlN, SiC or sapphire.

In one instantiation, the method of these teachings forming a quantum computing apparatus includes depositing superconducting layers and dielectric or semiconducting or metallic layers separating the superconducting layers by molecular beam epitaxy (MBE), a first superconducting layer being deposited on one surface of a substrate; and depositing Group III nitride layers for electronic components by metal-organic chemical vapor deposition (MOCVD).

### BRIEF DESCRIPTION OF THE DRAWINGS

FIG. 1A shows the current state of superconducting microwave qubits before integration;

FIGS. 1B and 1C show circuit-level diagram of components on chip after integration of these teachings;

FIG. 2 shows a proposed nitride-based material stack that can incorporate several different components in addition to qubits;

FIG. 2A shows TEM Image showing a structure of these teachings having a GaN HEMT on NbN with protective carbon on top;

FIG. 2B shows an enlargement of an area on the top of FIG. 2A as depicted in (a);

FIG. 2C shows an atomically arranged lattice showing the GaN HEMT;

FIG. 2D shows the Ga-polar structure of Al_{0.22}Ga_{0.78}N;

FIG. 2E shows interfaces of NbN/SiC;

FIG. 2F shows interfaces of AlN/NbN;

FIG. 2G shows the Al-polar AlN crystal structure from the boxed region in FIG. 2F;

FIG. 3 shows how the layer structure can be fabricated into different components of a quantum computer. Josephson junction qubits, bulk acoustic wave (BAW) filters, and HEMTs can be incorporated on one side of a chip, while travelling wave Josephson parametric amplifiers (TWPAs) can be connected through a substrate vias to the other side of the chip; Alternatively, one can also put the JJ qubits on one side of the chip and all other components on the other side;

FIGS. 4A and 4B shows cross-sectional scanning electron microscopy images of through substrate vias (TSVs) in one instantiation of these teachings;

FIGS. 5A-5C show structure and characteristics of a nitride-based HEMT of these teachings operating in the microwave frequency ranges that are suitable for superconducting microwave circuits;

FIG. 5D shows structure of a nitride-based p-FET as used in these teachings;

FIGS. 6A, 6B show instantiations of components of a quantum system-on-chip (q-SOC) of these teachings;

FIG. 7 shows a two-sided chip with the Josephson junctions insulated from the other components using hBN. Quantum computers require the qubits to be at the lowest temperature stage to maximize coherence; An hBN layer with low vertical thermal conductivity and high lateral conductivity can shield the qubits from heat and dissipate the heat elsewhere;

FIGS. 8A-8E shows quantum computer based on quantum dots; FIGS. 8A, 8B show a top down approach for forming quantum dots; FIG. 8C shows the direct epitaxy approach for forming quantum dots; FIG. 8D shows a quantum dot can be integrated into a qubit; FIG. 8E shows an energy diagram of the operation of the device in FIG. 8D;

FIGS. 9AI-9A-III diagrams how the quantum Hall effect (QHE) can be used in a quantum computer; FIG. 9A-III shows the traverse Hall resistance vs. gate voltage; FIG. 9B shows the quantum Hall effect (QHE) in a GaN HEMT; FIG. 9C shows the epitaxial semiconductor/superconductor heterostructure used in the measurements of FIG. 7A;

FIG. 10 shows a diagram illustrating how to use acoustoelectric coupling for filters that can communicate across both sides of the q-SOC of these teachings;

FIG. 11A shows a cross-sectional view of a coplanar waveguide as used in these teachings; and

FIG. 11B shows a top view of a coplanar waveguide as used in these teachings.

### DETAILED DESCRIPTION

Most of present day industrial quantum computers are based on superconducting microwave circuits and qubits and use a single layer of aluminum on silicon and are unable to monolithically integrate the qubits to their control electronics. An integrated chip for quantum computing can be enabled by using components based on epitaxial semiconductor and superconductor heterostructures. One instantiation of this could be based on the nitride material family. Due to recent advances in epitaxy [1], monolithic nitride layer stacks that can be fabricated into different components on the same chip can be made. Nitride-based heterostructures can serve as the basis of components such as microwave devices, bulk and surface acoustic wave filters, and Josephson junctions. Nitrides have already been shown to be great microwave devices [2] and bulk acoustic resonators [3] that can lead to filters. Nitrides have the potential to develop Josephson junctions, circulators, and other components that would be needed. Through advances in epitaxy, other material systems such as aluminum on arsenide semiconductors, could serve as platforms for an integrated chip as well.

“Group III,” as used here in, refers to a group of elements in the periodic table including what are now called Group 13 elements: boron (B), aluminum (Al), gallium (Ga), indium (In), thallium (TI).

“Group III nitrides,” as used here in, also include AlScN.

“Electrically conductive,” as used herein also includes superconductive.

“Low microwave loss material,” as used herein, refers to material having a loss tangent, at 30 GHz, smaller than 104. (See, for example, Ho Sang Jung et al., Microwave Losses of Undoped n-Type Silicon and Undoped 4H-SiC Single Crystals at Cryogenic Temperatures, Electron. Mater. Lett., Vol. 10, No. 3 (2014), pp. 541-549, John G. Hartnett et al., Microwave properties of semi-insulating silicon carbide between 10 and 40 GHz and at cryogenic temperatures, JOURNAL OF APPLIED PHYSICS 109, 064107 (2011), and P. A. Borodovskii et al., Microwave Characterization of Undoped Polycrystalline Silicon, Russian Microelectronics, 2006, Vol. 35, No. 6, pp. 350-353, all of which are incorporated by reference herein in their entirety and for all purposes.)

“Low thermal conductivity material,” as used here in, refers to material having a thermal conductivity, at 1° K, of less than 5.2×10⁻² W cm⁻¹° K⁻¹. (See, for example, T. Nemoto et al., Thermal conductivity of alumina and silicon carbide ceramics at low temperatures, Cryogenics 1985, Vol 25, September, pp. 531-532, and M. W. Wolfmeyer et al., The thermal conductivity of sapphire between 0.4 and 4° K, Physics Letters A, Volume 34, Issue 4, 8 Mar. 1971, Pages 247-248, all of which are incorporated by reference herein in their entirety and for all purposes.)

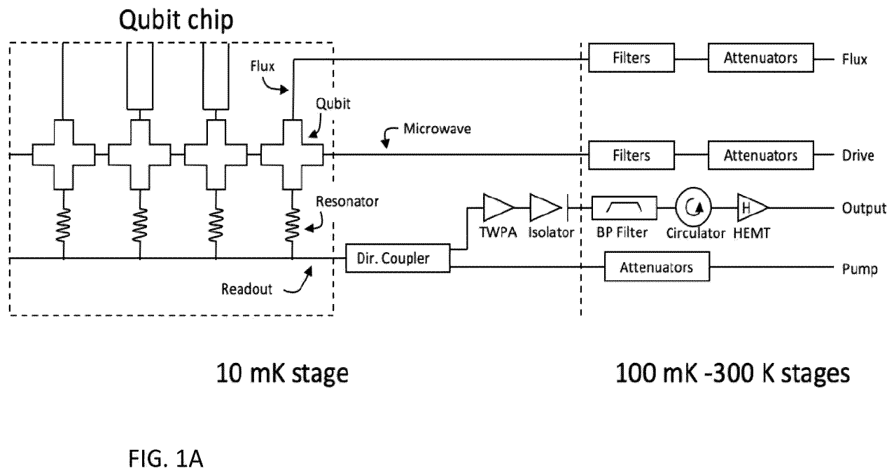

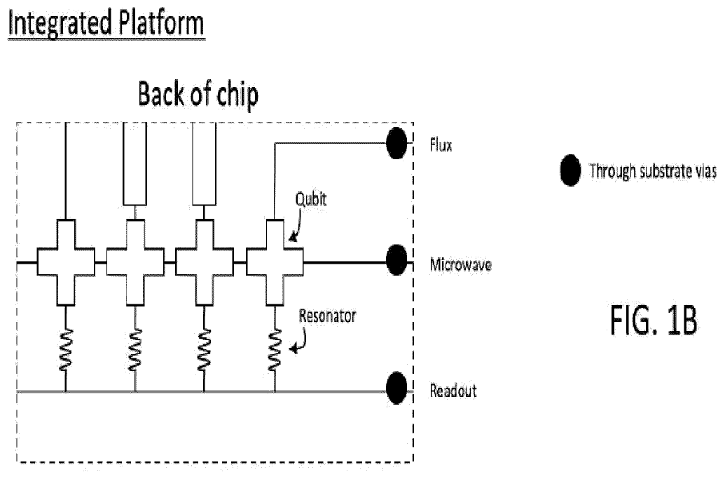

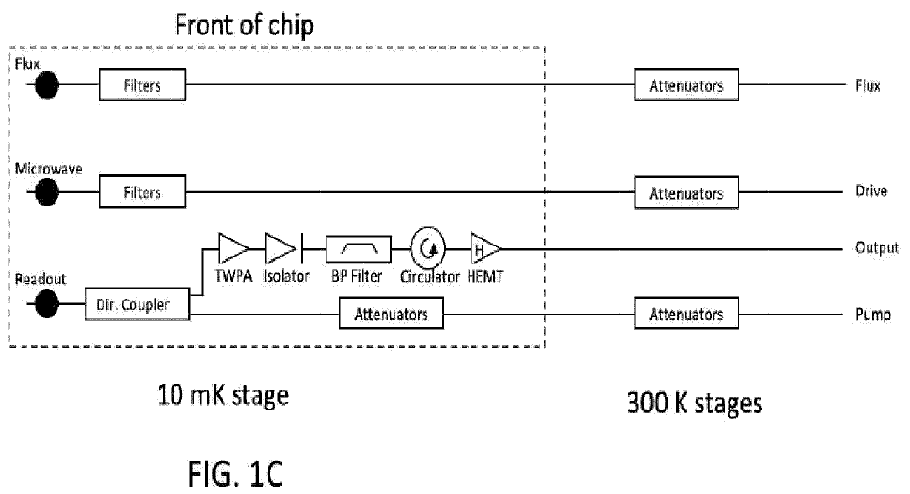

FIG. 1A shows the current state of superconducting microwave qubits before integration and shows an example of the current state of superconducting microwave qubits. The scheme consists of multiple temperature stages with the 10 mK stage being the temperature where the qubit must operate. The qubit chip sits at the lowest temperature stage and consists of the Josephson junction qubits, resonators for coherent coupling of the qubits, and interconnects that lead to the flux, drive, and output of the computer. All other components, such as amplifiers, transistors, filters, and circulators, sit outside the qubit chip across different stages the flux channel controls the frequency.

FIGS. 1B, 1C show circuit-level diagram of components on chip after integration of these teachings; Current superconducting quantum computers have qubits, resonators, and readout devices on the chip; With epitaxial integration, one can also add filters, amplifiers, and circulators to the chip; With sufficient heat shielding on-chip, one may also potentially remove various temperature stages on the computer and have operation at only 10 mK and 300 K.

With epitaxial integration, it is possible to add components, such as filters, amplifiers, and circulators, to the qubit chip via a monolithic process. With sufficient heat shielding on-chip, one can also potentially remove various temperature stages on the computer and have operation at only 10 mK and 300 K. FIGS. 1B, 1C show an instantiation of a computer where almost all components could operate on a single chip in the 10 mK stage, and only attenuators for heat shielding would need to sit off-chip at higher temperature stages.

Using the present teachings, length scales between qubits and off-chip components, such as filters, HEMTs, amplifiers, isolators, and circulators, are reduced from a few feet to 100s of micrometers. Also, using the present teachings, the number of temperature stages could be reduced to just 10 mK and 300 K.

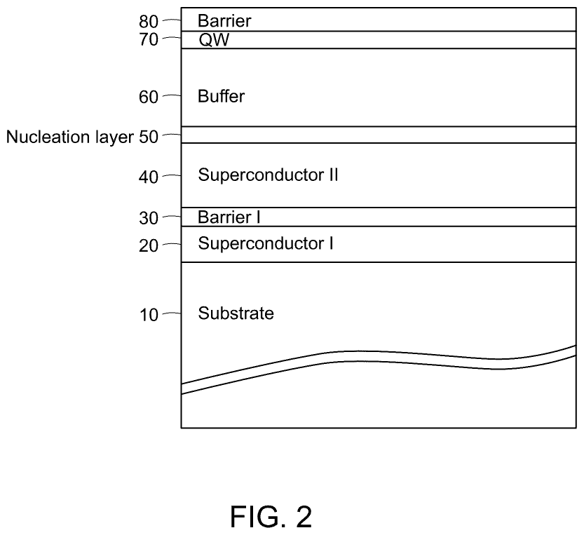

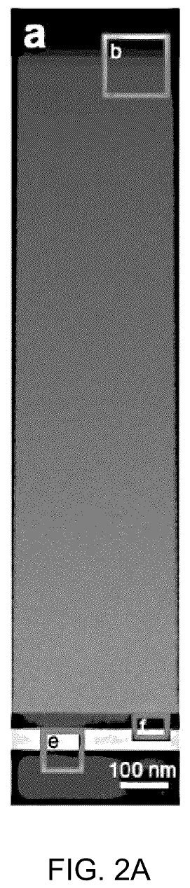

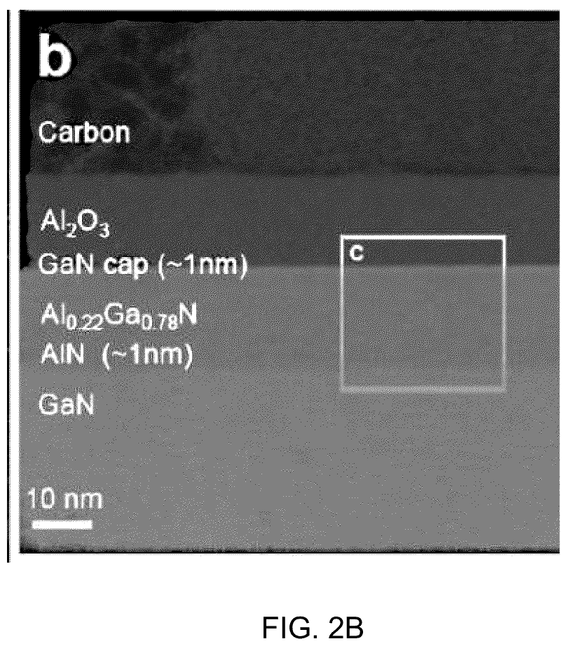

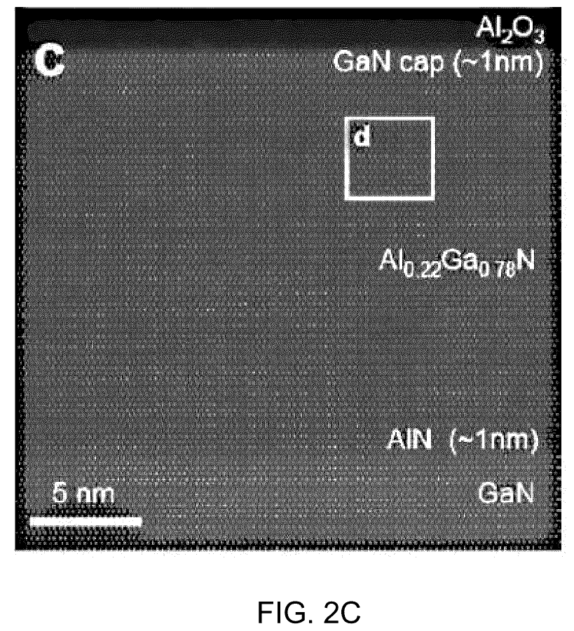

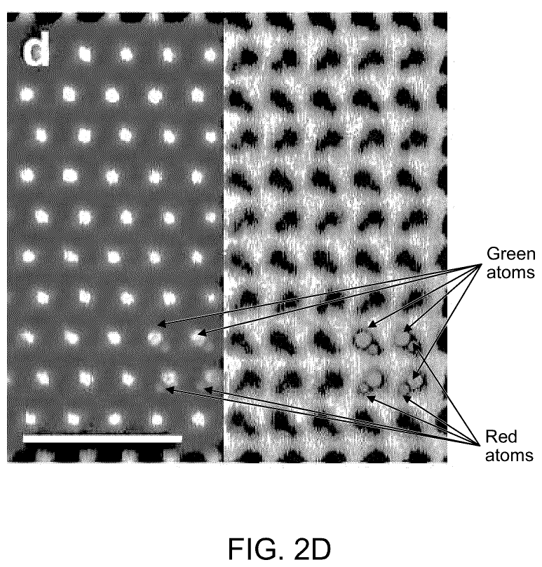

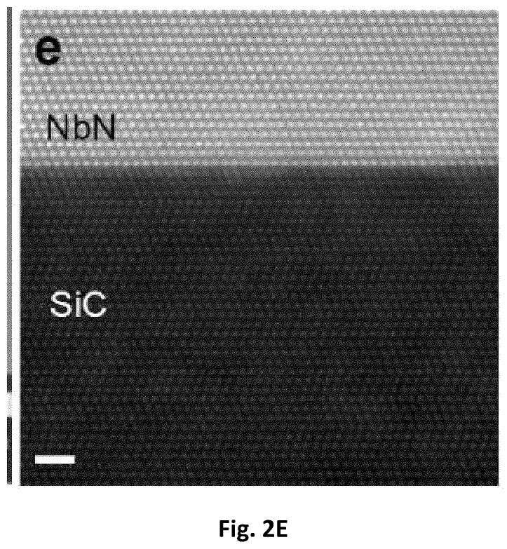

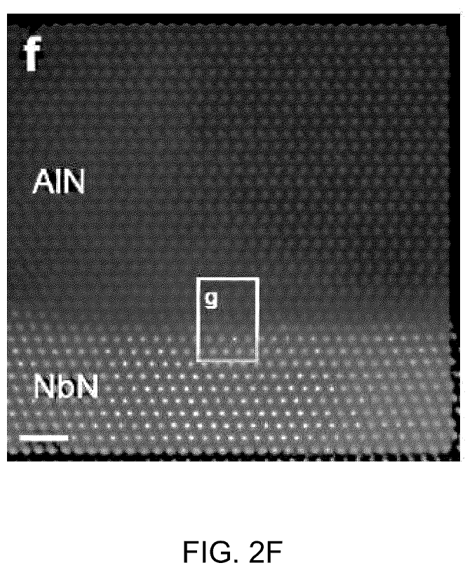

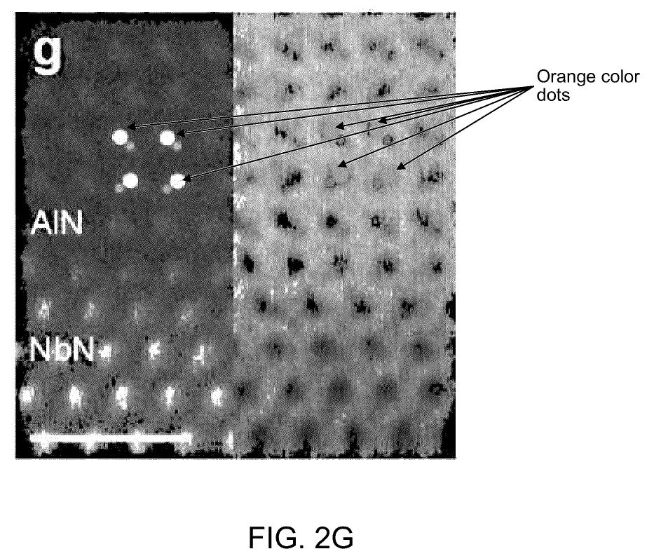

FIG. 2 shows a material stack that can incorporate several different components in addition to qubits. The heterostructure consists of a substrate 10, superconductor I 20, a barrier 30, superconductor II 40, a nucleation layer 50, buffer layers 60, a quantum well 70, and another barrier 80. From this single layered stack, one can create several components of a quantum computer in a single monolithic process. For example, the superconductor I/barrier I/superconductor II portion would form a Josephson junction (JJ), which serves as the qubit. The buffer layers can be made into bulk acoustic wave structures that serve as filters. The quantum well can be made into transistors that serve as amplifiers or compute.

This structure can have many instantiations with various materials able to fulfill the role of each layer. Advances in materials and devices from the nitride material system have enabled the epitaxial realization of such a structure, and the nitride family can provide several options for each layer. For example, the substrate can be >100 μm thick SiC, sapphire, Si, GaN, AlN, etc. The superconductors can be 10-500 nm of NbN, TiN, NbTIN, Nb, NbTi, etc. The bottom barrier can be 1-3 nm of AlN, GaN, ScN, AlScN, etc. The buffer layers can be a few μm thick of AlN, AlGaN, AlScN, etc. The quantum well of a few nm can be formed in a few-nm to few-μm-thick layer of GaN, InGaN, etc. The top barrier can be 1-30 nm of AlN, AlGaN, AlScN, etc.

The present teachings result in several off-chip components being brought “down” to the same chip as the qubits. This improvement is enabled by materials and device advances. These teachings offer a path to high frequency as a result of higher-temperature qubits.

2DEGs in AlGaAs/GaAs heterostructures are formed by intentional modulation doping of donor dopants in the wider bandgap semiconductor barrier. In AlGaN/GaN heterostructures, the 2DEG is of a fundamentally different origin: It is formed due to the Berry-phase driven electronic polarization discontinuity across the heterojunction (see Wood, D. Jena, Eds., Polarization Effects in Semiconductors (Springer US, Boston, MA, 2008). Therefore, the polarity (metal vs N polar) of the crystal uniquely determines the heterojunction at which the 2DEG is formed.

FIG. 2A shows TEM Image showing the overall structure of the GaN HEMT on NbN with protective carbon on top. FIG. 2B shows an enlargement of an area on the top as depicted in (a). The GaN cap and AlN layers have a slight change of contrast with respect to Al_{0.22}Ga_{0.78}N. FIG. 2C shows atomically arranged lattice showing the GaN HEMT. The boxed area in (c) is imaged in both high-angle annular dark field (HAADF) STEM (left) and annular bright field (ABF) STEM (right) images, shown also in FIG. 2D, which shows the Ga-polar structure of Al_{0.22}Ga_{0.78}N. The HAADF emphasizes the heavier atoms, while the ABF shows both. The labeled green atoms correspond to Ga while red atoms correspond to N. FIGS. 2E and 2F show the interfaces of NbN/SiC and AlN/NbN, respectively, which are located at the lower part of the GaN HEMT. FIG. 2G shows the Al-polar AlN crystal structure from the boxed region in FIG. 2F. Orange atoms correspond to Al. The scale bars are 1 nm unless otherwise noted.

FIG. 2A shows a scanning transmission electron microscopy (STEM) image of the entire heterostructure used in these teachings. FIGS. 2B and 2C zoom in on the nitride layers that contain the 2DEG. While the crystal lattice in the all-MBE heterostructure studied in R. Yan, G. Khalsa, S. Vishwanath, Y. Han, J. Wright, S. Rouvimov, D. Scott Katzer, N. Nepal, B. P. Downey, D. A. Muller, H. G. Xing. D. J. Meyer, D. Jena, GaN/NbN epitaxial semiconductor/superconductor heterostructures, Nature 555, 183-189 (2018), which is incorporated by reference herein in its entirety and for all purposes, (see also U.S. Patent Application Publication No. 2021/0043824, Epitaxial Semiconductor/Superconductor Heterostructures, which is incorporated by reference herein in its entirety and for all purposes) was N-polar in which the 2DEG was located above the epitaxial barrier layer, the MOCVD grown sample reported here is metal-polar, as shown in FIG. 2D. In FIG. 2D, the metal (larger circle) forms a chemical bond to the nitrogen atom (smaller circle) vertically above it: a finger-print of metal polarity. This positions the 2DEG below the epitaxial AlGaN barrier layer, as confirmed by the measured gate capacitance. Since the superconducting NbN layer is cubic and non-polar (FIG. 2C), the polarity in the structure begins with the AlN nucleation layer grown on NbN.

The metal polarity is seen to be fixed from this nucleation layer and is locked for all subsequent layers. This is evidenced by FIGS. 2F and 2G, where shown that the AlN nucleation layer is metal polar starting from the first layer grown on NbN. Therefore, the growth method of these teachings has the ability to control the polarity of the nitride heterostructure on top of NbN and enables precise engineering of the location of the 2DEG.

In these teachings, the NbN layer is grown by molecular beam epitaxy (MBE), and the GaN heterostructure, in which the 2DEG is formed at the heterojunction quantum well, is grown by metal-organic chemical vapor deposition (MOCVD)—the industrial tool for the production of nitride photonic and electronic devices in large scale.

In R. Yan, G. Khalsa, S. Vishwanath, Y. Han, J. Wright, S. Rouvimov, D. Scott Katzer, N. Nepal, B. P. Downey, D. A. Muller, H. G. Xing, D. J. Meyer, D. Jena, GaN/NbN epitaxial semiconductor/superconductor heterostructures, Nature 555, 183-189 (2018), weak Shubnikov-de Haas oscillations were observed in a 2DEG in a nitride heterostructure fabricated on NbN, both of which were grown epitaxially. The magneto-transport properties of the 2DEG in that study were far from the IQHE state, and the magnetic fields at which the SdH oscillations were observed were much larger than the critical Meissner field Hc of the epitaxial superconducting NbN. In these teachings, a modified epitaxial growth process is found to (A) lead to a much sharper Tc and a higher Hc of the superconducting NbN and (B) flip the crystal lattice polarity in the nitride heterostructure, resulting in a strong and clean Integral Quantum Hall Effect (IQH in the 2DEG of the HEMT. These improvements enable the two phenomena, IQHE (in the 2DEG) and superconductivity, to simultaneously occur in a single nanoscale device over a narrow range of temperatures and magnetic fields. The instantiations of these teaching described herein below a include the simultaneous occurrence of superconductivity and a 2DEG.

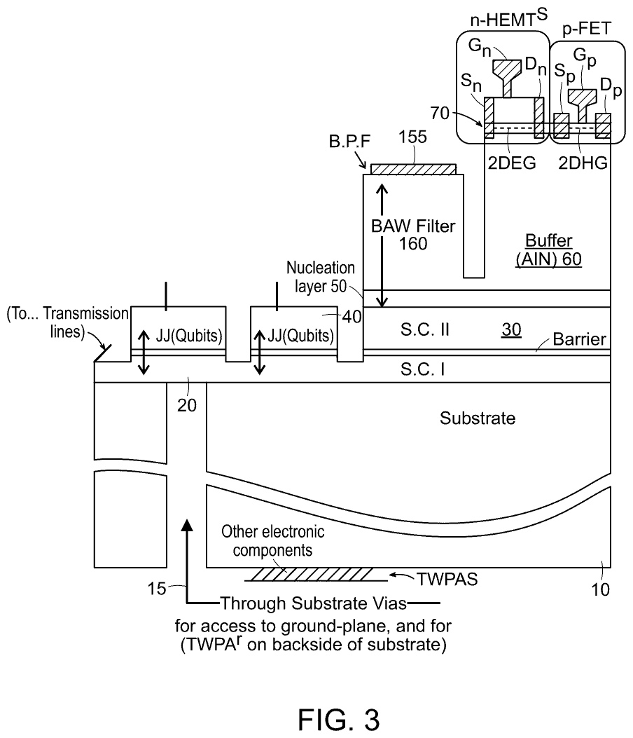

FIG. 3 shows how the layer structure from FIG. 2 (in which the layers have the same identifying numerals as in FIG. 2) can be fabricated into different components of a quantum computer. JJ qubits, bulk acoustic wave (BAW) filters 155, and high-electron-mobility transistors (HEMTs) can be incorporated on one side of a chip, while traveling wave Josephson parametric amplifiers (TWPAs) can be connected by a through substrate vias (TSV) to the other side of the chip. The BAW filters can act as a band pass filter (BPF), while the HEMTs can act as amplifiers. The HEMTs can also be created via nitride materials, which enables the use of two-dimensional electron gases (2DEGs) for n-type transistors (n-HEMTs) and two-dimensional hole gases (2DHGs) for p-type field-effect transistors (p-FETs). In this scenario, the nitride transistors also enable complementary metal-oxide semiconductor (CMOS) logic within a qubit chip. One or more electrically conductive material field through substrate vias 15 connect the first superconducting layer 22 other electronic components disposed on the surface of the substrate 10 opposite to the surface on which the first superconductor layer 20 is deposited. The other electronic components can include traveling wave parametric amplifiers (TWPAs), a variety of other components and ground planes.

The AlN BAW filter operates by forming a metal-insulator-metal acoustic cavity whose thickness determines the desired filter center frequency. Because of the piezoelectric property of AlN, the electromagnetic wave is converted to a sound wave of much smaller wavelength, while conserving the frequency, and thus the cavity resonator only allows those wavelengths that fit to pass through, rejecting the others. The figure of merit of this behavior is the product k2Q, where k2 is the electromechanical coupling coefficient, and Q is the quality factor of the resonator. Typical values are k2˜0.08 and Q˜5000 in the 1-10 GHz window. Since the thickness of AlN required to move to higher frequencies becomes deep sub-micron, the crystalline quality of the conventional sputtering technique poses significant challenges. The crystalline AlN used in nitride FETs and UV LEDs and Lasers have on the other hand managed to produce high quality AlN within 100 nm from the growth interfaces. Therefore, an advantage exists in using the epitaxial-AlN for fabricating BAWs. This metal electrodes have been deposited by epitaxy, realizing an all-epitaxial EpiBAW structure, in one instantiation, using NbN/AlN/NbN heterostructures (See Miller J, Wright J. Xing H G and Jena D 2020 Physica Status Solidi (A) Applications and Materials Science 217 2-7, which is incorporated by reference herein in its entirety and for all purposes). The crystalline and piezoelectric properties of the epitaxial AlN layers have to be controlled, undesired lateral edge modes have to be avoided, and the resistance of the metal electrodes has to be controlled, which thickness should also be scaled in tandem with the thickness of the AlN layers themselves.

In the instantiation where the buffer layer is AlN, the incorporation of an aluminum nitride buffer improves upon existing n-type GaN amplifiers and allow for the inclusion of high-current p-type transistors on the same heterostructure. Aluminum nitride also enables integration of both bulk acoustic wave (BAW) filters and substrate-integrated waveguides (SIW) and filters based on SIWs, providing a fully integrated monolithic RF signal-processing solution. (See U.S. Patent Publication No. ______, for U.S. patent application Ser. No. 17/554,511. INTEGRATED ELECTRONICS ON THE ALUMINUM NITRIDE PLATFORM, filed on Dec. 17, 2021, claiming priority of U.S. Provisional Application No. 63/128,044, all of which are incorporated by reference herein in their entirety and for all purposes.)

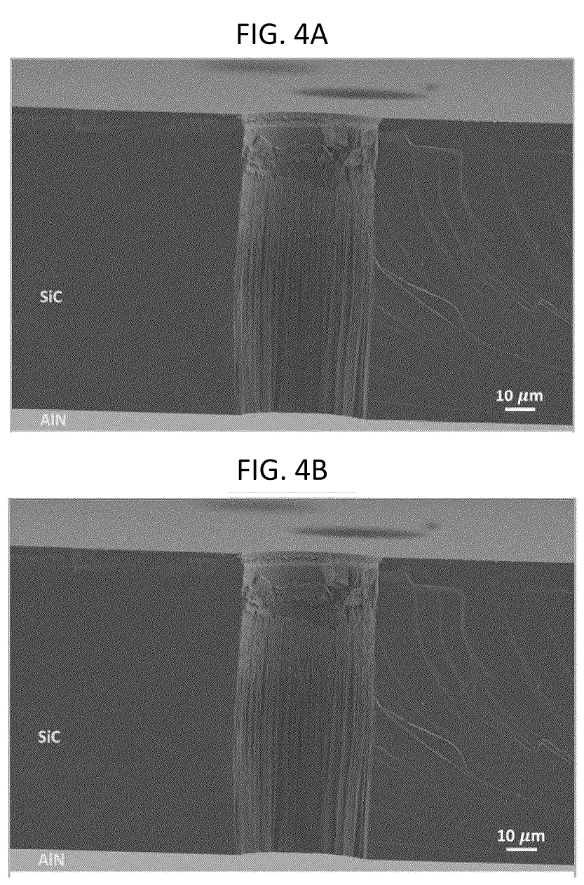

FIGS. 4A, 4B show cross-sectional scanning electron microscopy images of TSVs in SiC that can be shaped as (a) circles or (b) hexagons. The TSVs were created by inductively coupled plasma reactive ion etching of a 100 micrometer SiC with 300 nm of AlN underneath. The AlN underneath SiC is left unetched. This demonstration of controlled TSV fabrication enables the instantiations of quantum system-on-chips (Q-SOCs) where two-sided chips are used for integrated quantum computing.

The above instantiation of these teachings provides the ability to fabricate components on two sides of the same chip. Connections between two-sides are based on nitride components on low microwave loss, low thermal conductivity substrate (such as, for example, SiC) heterostructures. Thermal insulation between the two sides is provided by the (100 micrometers in one instance) low loss, low thermal conductivity substrate (such as, for example, SiC).

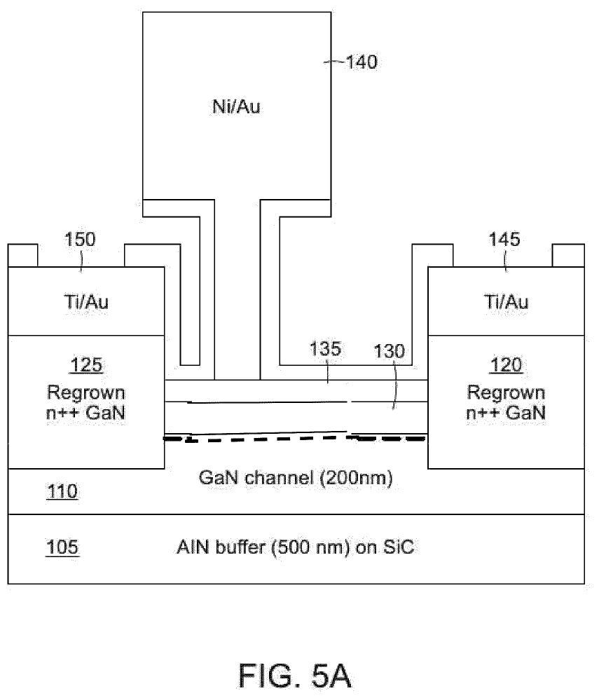

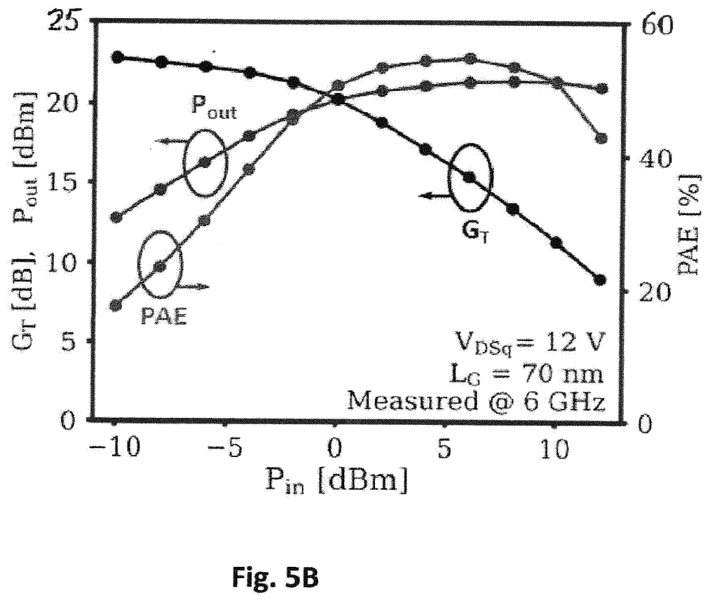

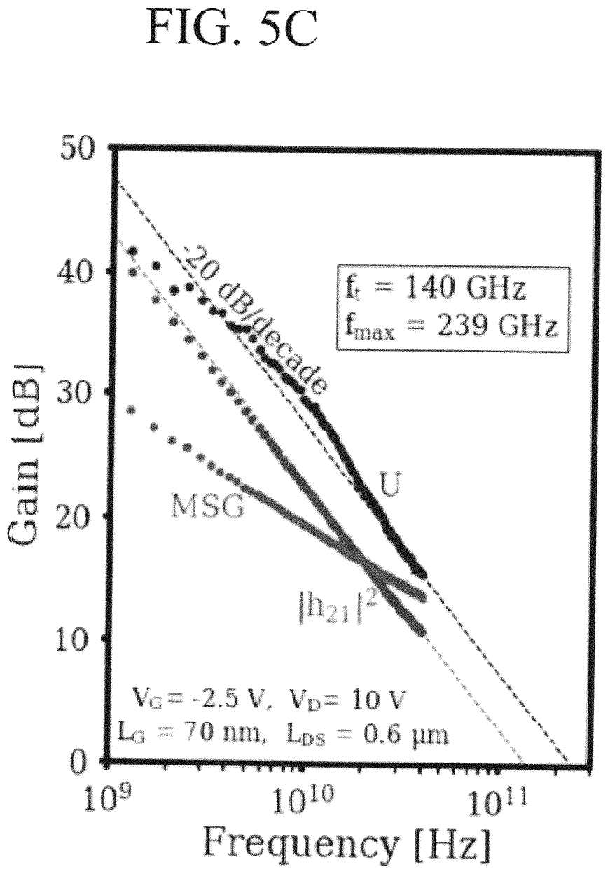

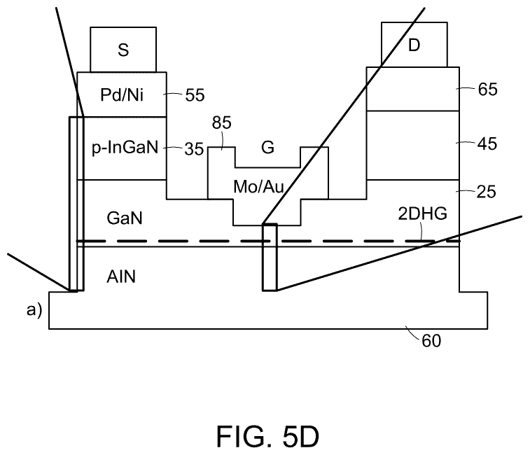

FIGS. 5A-5C shows a nitride-based HEMT operating in the microwave frequency ranges that are suitable for superconducting microwave circuits, FIG. 5A shows the nitride HEMT. FIG. 5C shows the small signal characteristics at varying microwave frequencies. In FIG. 5C, Red (|h₂₁|²) data is the current gain, blue data (U) is unilateral gain, and green data is the maximum stable gain (MSG). The device has a roll-off of −20 dB/decade from 1-30 GHZ, which is used to extrapolate a maximum frequency (fₘₐₓ) of 239 GHz. Therefore, the HEMT shows operation for a large range of microwave frequencies.

Referring to FIG. 5A, in the instantiation shown therein, an AlN/GaN/AlN power amplifier is shown, including an AlN buffer layer 105 formed on a substrate, such as SiC. Aluminum oxide, Silicon, AlN, Sapphire or the like. The AlN buffer layer 105 is formed to a thickness in a range between about 350 nm to about 500 nm, although other thicknesses are within the scope of these teachings. A GaN channel layer 110 is epitaxially grown on the AlN buffer layer 105 so that the lattice of the GaN channel layer 110 is matched to the lattice of the AlN buffer layer 105. The GaN layer 110 is selected such that a 2D Hole gas form at the AlN/GaN heterostructure. Although a GaN thickness of 30 nm is shown, other thicknesses are within the scope of these teachings. Other materials, besides GaN, are also within the scope of these teachings. An AlN barrier layer 130 is formed on the GaN channel layer 110. A 2D electron gas forms at the GaN channel layer/AlN barrier layer heterostructure. A GaN cap layer 135 formed on the AlN barrier layer 130. Although to a thickness of about 2 nm is shown for the cap layer 135, other thicknesses may be used. Source and drain recesses are formed spaced apart in the power amplifier materials stack and provide for the formation of n++ GaN source and drain regions 120 and 125, respectively. Ohmic contacts 145, 150 are formed on the n++ GaN source and drain regions 120 and 125. In some instantiations, the ohmic contacts include a metal or a combination of metals, such as Ti and/or Au. Other metals may also be used. A gate electrode 140 includes a neck portion, the neck portion having a first width, and second portion, disposed on the first portion, and having an average width larger than the first width is formed, the neck portion being disposed on the GaN cap layer 135. A passivation layer is be formed over the ohmic contacts 145, 150, the T-shaped gate electrode 140 and the GaN cap layer 135.

FIG. 5B shows the transducer gain (G_{T}), power-added efficiency (PAE), and output power (Pₒᵤₜ) of the nitride HEMT as a function of input power (Pᵢₙ) at 6 GHZ. The device shows a maximum PAE of 55% and maximum Pₒᵤₜ of 2.8 W/mm, showing that the device acts as an efficient amplifier at microwave frequencies suitable for superconducting microwave circuits. Nitride devices are therefore able to serve in the TWPA and as HEMT in quantum computers.

FIG. 5C is a graph showing the small-signal characteristics for an instantiation, AlN/GaN/AlN, of a nitride HEMT device with LG=70 nm, with a resulting ft/fmax=140/239 GHz in some instantiations according to these teachings.

A cross section of an instantiation of a nitride based p-FET, is shown in FIG. 5D. (See Bader S J, Chaudhuri R. Hickman A, Nomoto K, Bharadwaj S. Then H W, Xing H G and Jena D 2019 Technical Digest—International Electron Devices Meeting, IEDM 2019 Dec. 4-7; U.S. Patent application Publication No. 2020/0144407, by Bader et al., published May 7, 2020, all of which are incorporated by reference herein in their entirety and for all purposes.) Referring to FIG. 5D, the interface between the not intentionally doped second Group III nitride material (GaN in the instantiation shown) and the not intentionally doped Group III nitride buffer material (AlN in the instantiation shown) yields a 2DHG. Continuing to refer to FIG. 5D, in the instantiation shown there in, a layer of not intentionally doped second Group III nitride material 25 (GaN in the instantiation shown) and the has a first indentation extending from a first surface on which the first slab of p-doped third Group III nitride material 35 (p-doped InGaN instantiation shown) and the second slab of p-doped third polar Group III nitride material 45 are disposed to a second surface disposed between the first surface and a surface in contact with the layer of a not intentionally doped AlN Group III nitride buffer material 60. A second indentation extends from the surface of the first indentation to a surface between the surface of the first indentation and the surface in contact with the layer of a not intentionally doped Group III nitride buffer material 60. The second indentation is disposed between the first and second slabs of p-doped third Group III nitride material 35, 45. The third electrically conductive contact 85 substantially fills the second indentation in the layer of the not intentionally doped second Group III nitride material 25 (GaN in the instantiation shown).

These teachings provide good power output and high efficiency for nitride based HEMTs at microwave frequencies. The nitride HEMTs can operate as amplifiers in microwave circuits.

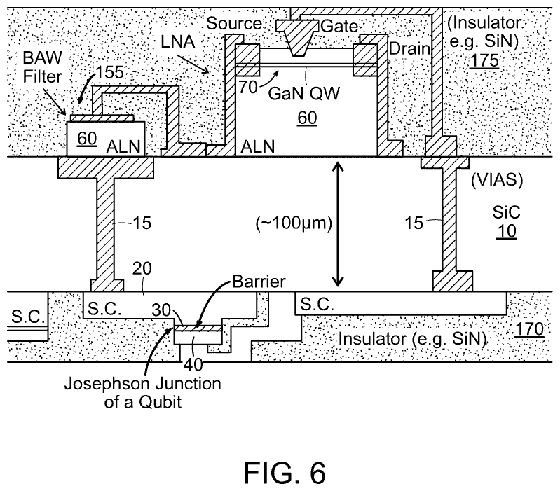

Epitaxial integration of the different components enables many possible chip designs. In this instantiation, the JJ qubits, filters, and transistors are grown and fabricated on the same side of the chip. Alternatively, one can also put the JJ qubits on one side of the chip and all other components on the other side, as shown in FIG. 6c

FIG. 6 shows one instantiation of a system-on-chip (identifying numbers are the same as in previous figures, in order to recognize the common thread). The substrate 10 (SiC in the instantiation shown in the figure) is a thermal insulator that can provide heat shielding between the two sides of the chip. The bottom of the chip contains the Josephson junction qubits, consisting of superconductor 20/barrier 30/superconductor 40 structures. The superconducting contacts of the Josephson junctions are connected to the top of the chip by Through-substrate vias (TSVs) 15. The top of the chip contains an AlN BAW filter 155 and a low-noise amplifier (LNA) that is based on a GaN HEMT. An insulator 170,175 (SiN in the instantiation shown) is deposited on both sides of the chip for further insulation. By utilizing an epitaxial nitride platform and providing sufficient heat shield through thermally insulating materials and spatial separation of the components, a system on chip can also be realized. Instantiations in which a different insulator is deposited on the side of the chip are also within the scope of these teachings.

This structure can be realized with the components repeated in an array laterally where the array is grown and processed together. The lateral array can then be stacked vertically with metallic BUMP contacts (interconnects) enabled by the superconducting TSV. This allows for 3D arrays of qubits with integrated measurement, filtering, etc. components, increasing the quantum computing power.

By taking advantage of 3D arrays of superconducting qubits, more complex quantum computing logic can be handled. Quantum computing is limited by the qubit coherence time and signal speed (which includes signal delay in the electronics/interconnects). Only qubits in the volume enclosed by a sphere of radius˜(qubit coherence time)*(signal speed).

This instantiation is made possible by a number of advantages, some of which are pointed out here in below. The materials used as a substrate (such as, but not limited to, SiC, used in the detailed instantiation shown) become thermal insulators at temperatures <1 K, enabling the materials to be a good platform for qubits. The low noise amplifier (LNA) and filters are integrated on one side, while the qubits and superconducting electronics are on the other side (the separation can also apply to other components such as TWPA). The TSVs allows connections between the two sides of the chip. The distance between a Josephson junction qubit to a filter and HEMT is reduced from a few feet to ˜100 micrometers.

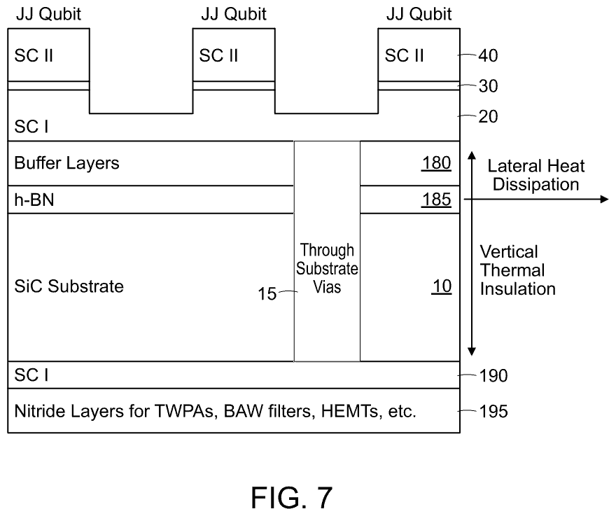

FIG. 7 (in which the layers have the same identifying numerals as in FIG. 2) shows a two-sided chip with the Josephson junction qubits insulated from the other components using a layer of dielectric or semiconductor material with anisotropic heat transfer properties 185 (hexagonal boron nitride (h-B) in the instantiation shown there in) The anisotropic heat transfer properties, in the materials used, provide a higher heat transfer coefficient along the layer than across the layer. (See, for example, Puqing Jiang, Xin Qian, Ronggui Yang, and Lucas Lindsay, Anisotropic thermal transport in bulk hexagonal boron nitride, Phys. Rev. Materials 2, 064005 (2018), which is incorporated by reference herein in its entirety and for all purposes.) One or more buffer layers 180 are disposed between the first layer of superconductor material 20 and the layer of dielectric or semiconductor material with anisotropic heat transfer properties 185. Quantum computers require the qubits to be at the lowest temperature stage to maximize coherence. An h-BN layer 185, 1-500 nm thick, with low vertical thermal conductivity and high lateral thermal conductivity can shield the qubits from heat and dissipate the heat elsewhere. In this instantiation, the h-BN would be placed in an interlayer between the two sides of the chip and provide insulation between the two sides of the chip. This is in addition to the thermal insulation provided by the SiC substrate and SiN in FIG. 5, which would further protect the qubits from heat. The instantiation of these teachings shown in FIG. 7 also has a layer of superconductor material 190 disposed on the opposite surface of the substrate 10 (SiC in the instantiation shown, although a number of other substrates are within the scope of these teachings). The layer of superconductor material 190 can be patterned and other layers of superconductor material deposited and patterned in order to provide connectors, Josephson junctions and other configurations, as needed. This enables the fabrication of Josephson traveling wave parametric amplifiers, superconducting transmission lines (including strip lines), waveguides, another components. Nitride layers 195 (which can include the buffer layer 60) are deposited on the superconducting layer 190 and open surfaces of the substrate 10. The nitride layers are used in the fabrication of TWPAs, filters, HEMTs, and other components.

The instantiations of FIGS. 2-7 can be used for all the different types of superconducting qubits-Cooper pair boxes, transmons (Jens Koch et al., Charge insensitive qubit design derived from the Cooper pair box, arXiv:cond-mat/0703002v2 [cond-mat.mes-hall] 26 Sep. 2007), fluxonium (Vladimir E. Manucharyan et al., Fluxonium: Single Cooper-Pair Circuit Free of Charge Offsets, Science 2 Oct. 2009: Vol. 326, Issue 5949, pp. 113-116) and others.

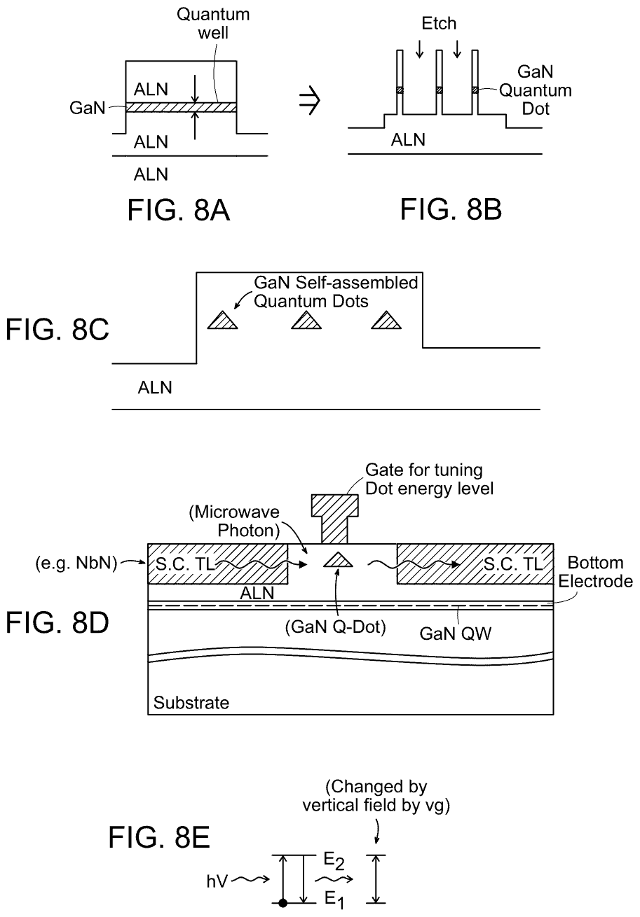

FIGS. 8A-8E show a quantum computer based on quantum dots instead of Josephson junctions. FIGS. 8A-8E show how components of a quantum dot-based quantum computer could also be realized with an epitaxial material system, such as the nitrides. FIGS. 8A, 8B shows a top-down approach for creating the quantum dots. Each quantum dot has a nanocolumn structure having a Group III nitride buffer layer, a first Group III nitride thin layer epitaxially deposited on at least a portion of the Group III nitride buffer layer, and a second Group III nitride layer epitaxially deposited on the first Group III nitride layer. In one instance, materials and thickness of the first Group III nitride layer and the second Group III nitride layer selected such that electronic polarization discontinuity across a heterojunction between the first Group III nitride layer and the second Group III nitride layer causes formation of a 2D electron gas (2DEG) below the second Group III nitride layer, In the instantiation shown in FIGS. 8A, 8B, an AlN (10 nm to few microns) (second Group III nitride layer)/GaN (2-10 nm) (first Group III nitride thin layer)/AlN (10-100 nm) (Group III nitride buffer layer) stack forms a quantum well, and the stack would be etched down for the quantum wells to become quantum dots that are 2-10 nm in length and width.

FIG. 8C shows a direct-epitaxy approach, where growth advances in GaN have allowed the direct location of self-assembled quantum dots. (For self assembly, see, for example, Pierre M. Petroff, Axel Lorke, and Atac Imamoglu, Epitaxially Self-Assembled Quantum Dots,: Physics Today 54, 5, 46 (2001), which is incorporated by reference herein in its entirety and for all purposes.) FIG. 8D shows how a quantum dot (made with the direct-epitaxy approach) can be integrated into a qubit. Microwave photons are transmitted to the quantum dot through a superconducting (e.g., NbN) transmission line (SCTL). A gate on top of the quantum dot allows timing of the dot energy level. Underneath the quantum dot is an AlN/GaN/AlN stack that forms a 2DEG, which can be used as a bottom electrode. FIG. 8E shows an energy diagram of the operation of the device in FIG. 8D. The quantum dots of these teachings can be used in the configurations described in Christoph Kloeffel and Daniel Loss, Prospects for Spin-Based Quantum Computing in Quantum Dots Annual Review of Condensed Matter Physics 2013 4:1, 51-8, which is incorporated by reference herein in its entirety and for all purposes.

Quantum Hall Effect (QHE) is a topological state that produces extremely precise resistances and, therefore, is used as the modern resistance standard. QHE can act as a protected resistance reference for low noise circuits.

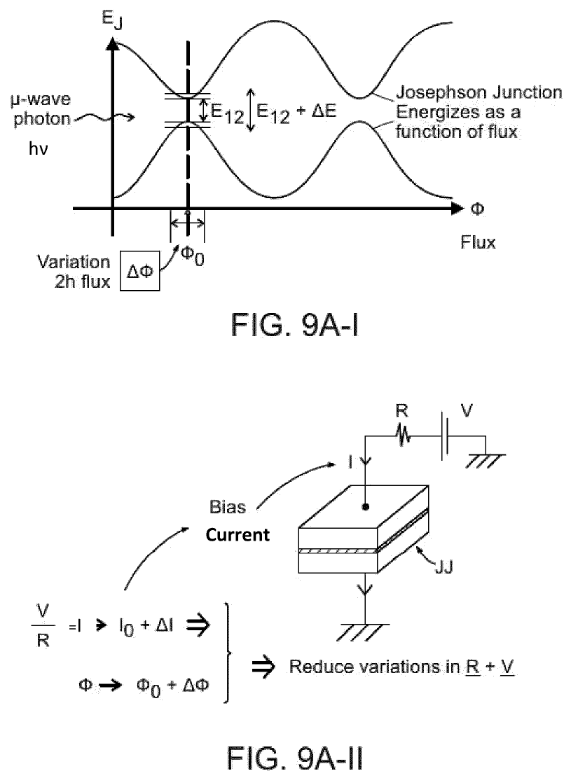

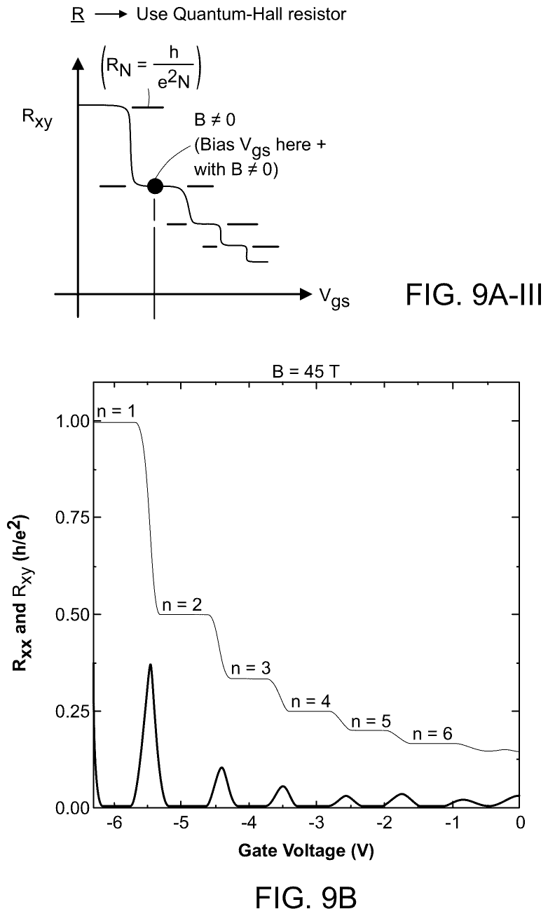

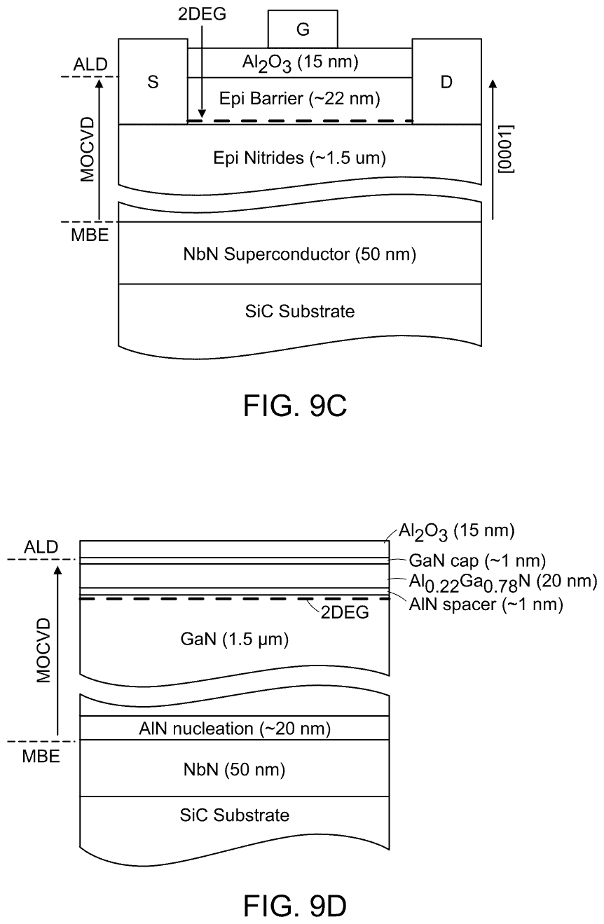

FIG. 9A-I to 9A-III diagram how the QHE can be used in a quantum computer. FIG. 9A-II diagrams the effect of a variation in flux; FIG. 9A-III shows the traverse Hall resistance vs. gate voltage. Nitride 2DEG could essentially act as an extremely precise (part-per-billion) resistor that feeds into a Josephson junction qubit. When the 2DEG is in the quantum Hall state, its Hall resistance becomes quantized with precise values of h/(e²n), where n is an integer, h is the Planck constant, and e is the electron charge. A reduction in resistance variations would decrease variations in the JJ flux, which would enable more precise JJ energy levels for microwave photons to excite. Precise microwave frequencies associated with each qubit means qubits are less likely to unintentionally interfere with each other, which decreases error rates.

FIG. 9B shows an experimental demonstration of the QHE in a GaN HEMT that was grown on superconducting NbN. The measurement was taken at 45 T and 390 mK while varying the number of carriers in the 2DEG via a gate voltage. The red line shows well-defined Hall resistance (R_{xy}) values, and the black line shows the associated quantized Rₓₓ values. This demonstration shows that the concept in FIG. 9A is experimentally achievable.

The above instantiation of these teachings results in low error JJ qubits enabled by extremely precise quantum Hall resistors. The demonstration of QHE in a nitride HEMT grown on a superconductor shows that a QHE resistor feeding into a JJ can be achieved in a single structure and/or chip. The results of FIG. 9B were obtained in an epitaxial heterostructure in which the 2DEG of the high electron mobility transistor (HEMT) exhibits the integer quantum Hall effect in a regime where an underlying, spatially separated superconductor retains its superconducting properties.

FIG. 9B shows the longitudinal and transverse magnetoresistance Rxx and Rxy of the 2DEG measured in a gated Hall bar at 45 T and 390 mK. The n=1, 2, IQHE plateaus are clearly resolved in the Hall resistance Rxy, accompanied by the vanishing of the longitudinal magnetoresistance Rxx when the Fermi level is in the gap between Landau levels, the hallmark of the quantum Hall insulating phase. The transition between the plateaus of the QHE states is accompanied by peaks in the Rxx when the Fermi level is located inside a Landau level.

FIG. 9C shows an instantiation of the epitaxial semiconductor/superconductor heterostructure. The NbN layer is grown by molecular beam epitaxy (MBE), and the GaN heterostructure, in which the 2DEG is formed at the heterojunction quantum well, is grown by metal-organic chemical vapor deposition (MOCVD). The 50 nm thick NbN layer was grown epitaxially by plasma-assisted MBE on a 3-inch diameter semi-insulating Si-face 6H-SiC wafer that was chemical-mechanically polished to an epi-ready finish using equipment and methods discussed in R. Yan, G. Khalsa, S. Vishwanath, Y. Han, J. Wright, S. Rouvimov, D. Scott Katzer, N. Nepal, B. P. Downey, D. A. Muller, H. G. Xing, D. J. Meyer, D. Jena, GaN/NbN epitaxial semiconductor/superconductor heterostructures, Nature 555, 183-189 (see also U.S. Patent Application Publication No. 2021/0043824, Epitaxial Semiconductor/Superconductor Heterostructures). FIG. 9D shows another of the epitaxial semiconductor/superconductor heterostructure of these teachings.

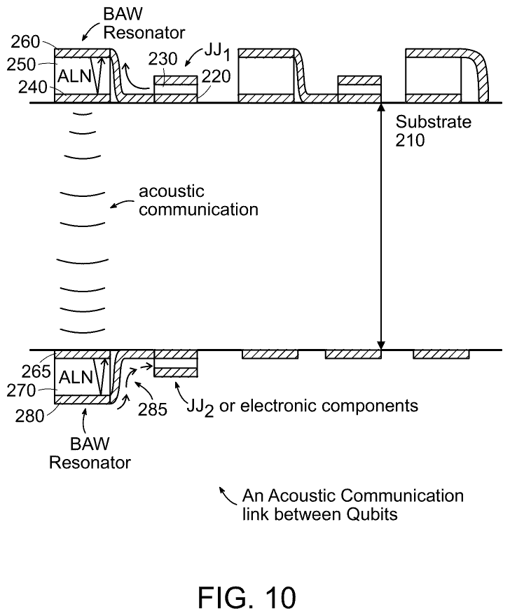

FIG. 10 shows a diagram illustrating how to use acoustoelectric coupling for filters that can communicate across both sides of the Q-SOC. BAW-based nitride devices can act both as filters, as previously mentioned, and resonators. BAW resonators can convert a microwave signal into an acoustic signal that transmits to other BAW resonators. Since the acoustic waves travel through the bulk of materials, it can communicate through substrates such as AlN, SiC, and sapphire. This enables communication between JJ qubits that are on opposite sides of a chip, which would allow for an increase in qubit density.

Referring to FIG. 10, in the embodiment shown there in, a first layer of semiconductor material 220 is disposed on one surface of the substrate 210. A layer of insulating (or metallic or semiconducting in other instantiations) material 230 is disposed on the first layer of semiconductor material 220 and a third layer of semiconducting material 230 is disposed on the layer of insulating material, forming a Josephson junction (JJ), forming quantum processing elements. A first layer of electrically conductive material 240 is disposed over another section of the substrate 210. A first layer of not intentionally doped AlN 250 is deposited over the first layer of electrically conductive material 240 and a second layer of electrically conductive material 260 is disposed over the first layer of not intentionally doped AlN 250, forming a first bulk acoustic wave (BAW) filter. The second layer of electrically conductive material 260 is operatively connected to the quantum processing elements. A third layer of electrically conductive material 265 is deposited over a section of an opposite surface of the substrate 210. A second layer of not intentionally doped AlN 270 is deposited over the third layer of electrically conductive material 265. A fourth layer of electrically conductive material 280 is deposited over the second layer of not intentionally doped AlN 270, forming a second BAW filter. The fourth layer of electrically conductive material 280 is operatively connected to electronic components by electrically conductive connector 285. The electronic components can include other quantum processing components, such as JJs.

The above instantiation of these teachings provides a not previously available mode of communication between quantum computing components enabled by acoustoelectric coupling. In the instantiation shown in FIG. 10, communication between two sides of the same chip is enabled by BAW communication. Higher qubit densities are enabled by the ability to have coupled JJ qubits on two sides of the same chip.

The other component used in quantum computing systems can also be fabricated by the methods of these teachings,

Circulators, which are used in some quantum computing systems, can also be fabricated by epitaxial processes (see, for example, [6] Tinghao Liang, Self-bias On-chip Nanoferrite Circulator for CMOS Integration: Design, Fabrication and Measurement, thesis submitted for the Master of Science, Tufts University, February 2017). In one embodiment of an integrated circulator—a microwave hexaferrite disk circulator, which can be fabricated by the methods of these teachings.

Another component that is found in some quantum computing systems is a traveling wave parametric amplifier (TWPA). In some instantiations, the TWPA also includes Josephson junctions (see, for example, C. Macklin et al. A near-quantum-limited Josephson traveling-wave parametric amplifier, Science Express, 3 Sep. 2015, or U.S. Pat. No. 10,873,302, issued on Dec. 22, 2020 to B. K. Tan, both of which are incorporated by reference herein in their entirety and for all purposes.) The TWPA can be fabricated by the methods described above.

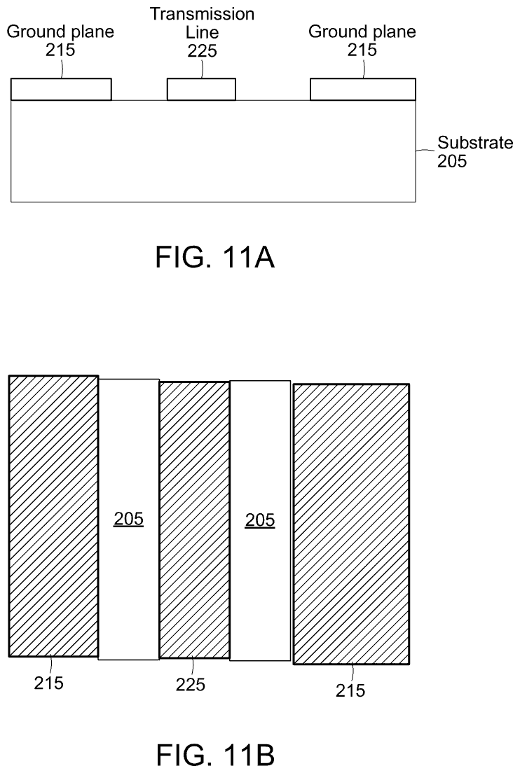

Reading and communication of qubits is sometimes enabled by resonators. Resonators are built from superconducting or electrically conducting transmission lines or waveguides. One possible waveguide is a coplanar waveguide geometry, shown in FIGS. 11A and 11B. FIG. 11A show the cross-sectional view of a typical coplanar waveguide. FIG. 11B show the top view of a coplanar waveguide geometry. Ground planes 215 and a transmission component 225 are disposed over a substrate 205. Strip line configurations are also sometimes used. In a strip line configuration, a transmission line component is disposed over a layer of dielectric material and a ground plane component is disposed on an opposite surface of the layer of dielectric material. (See, for example, SUPERCONDUCTING COPLANAR WAVEGUIDE RESONATORS FOR QUANTUM COMPUTING, Final Master Project by Alberto Lajara Corral, Universitat Autonoma de Barcelona, May 2020, which is incorporated by reference herein in its entirety and for all purposes.) Stripline and coplanar waveguides can be fabricated according to these teachings. Other designs for semiconductive waveguides are provided in U.S. Pat. No. 10,686,007, Quantum circuit assemblies with at least partially buried transmission lines and capacitors, by Hubert C. George, issued on Jun. 16, 2020, which is incorporated by reference herein in its entirety and for all purposes.

Substrate integrated waveguides (SIWs), as presently manufactured, use metallized vias to realize the edge walls (and also end walls) (The structure of SIWs has been shown in D. Deslandes et al., “Dispersion characteristics of substrate integrated rectangular waveguide,” IEEE Microwave Wireless Compon. Lett., vol. 12, pp. 333-335, September 2002, to have the same guided wave characteristics as a rectangular waveguide with equivalent width. Design rules and design considerations for a structure are provided in Dominic Deslandes, and Ke Wu, Accurate Modeling, Wave Mechanisms, and Design Considerations of a Substrate Integrated Waveguide, IEEE Transactions on Microwave Theory and Techniques, VOL. 54, NO. 6, June 2006, pp. 2516-2526. Both of these publications are incorporated by reference herein in their entirety and for all purposes.) SIWs can be manufactured as detailed in U.S. Patent Publication No. ______, for U.S. patent application Ser. No. 17/554,511, INTEGRATED ELECTRONICS ON THE ALUMINUM NITRIDE PLATFORM, filed on Dec. 17, 2021, claiming priority of U.S. Provisional Application No. 63/128,044, all of which are incorporated by reference herein in their entirety and for all purposes.

The waveguide formed by the first and second group of metallized vias and the third and fourth conductive layers, when substantially closed at each end, leaving an opening for input and output of electromagnetic radiation, forms a resonance cavity. When a second number of metallized vias is disposed between the two ends, two resonance cavities can be formed. If the second number of metallized vias leaves an opening so that the two resonance cavities can communicate, the structure can be designed to be a filter. (See, for example, Xiao-Ping Chen and Ke Wu, Substrate Integrated Waveguide Filter, IEEE Microwave Magazine, July/August 2014. pp. 108-116, and Li Y. Yang L A. Zou H. Zhang H S, Ma X H and Hao Y 2017 IEEE Electron Device Letters 38 1290-1293, both of which are incorporated by reference here in in their entirety and for all purposes.)

In one instantiation, the method of these teachings forming a quantum computing apparatus includes depositing superconducting layers and dielectric or semiconducting or metallic layers separating the superconducting layers by molecular beam epitaxy (MBE), a first superconducting layer being deposited on one surface of a substrate; and depositing Group III nitride layers for electronic components by metal-organic chemical vapor deposition (MOCVD).

In one instance, a not intentionally doped metal-polar Group III nitride nucleation layer on portion of a last superconducting layer by MOCVD. A first Group III nitride layer for electronic components on the not intentionally doped metal-polar Group III nitride nucleation layer by MOCVD. The superconducting layers and the dielectric or semiconducting or metallic layers separating the superconducting layers are patterned, under another portion of the last superconducting layer, in order to obtain a plurality of quantum processing elements arranged in a matrix. One or more vias are patterned through the substrate under the other portion of the last superconducting layer and filled with electrically conductive material. The filled vias are connected to other components disposed on an opposite surface of the substrate.

In another instance, the Group III nitride layers for electronic components are deposited on an opposing surface of the substrate. One or more vias are patterned through the substrate under the other portion of the last superconducting layer to provide an electrical connection from each of the electronic components to one of the superconducting layers and the vias filled with electrically conductive material. The superconducting layers and the dielectric or semiconducting or metallic layers separating the superconducting layers are patterned, under another portion of the last superconducting layer, in order to obtain a plurality of quantum processing elements arranged in a matrix. In a further instance, a first insulating material is deposited over the plurality of quantum processing elements arranged in a matrix and the one surface of substrate, and a second insulating material is deposited over the electronic components and the opposing surface of the substrate.

For the purpose of better describing and defining the present teachings, it is noted that terms of degree (e.g., “substantially.” “about.” and the like) may be used in the specification and/or in the claims. Such terms of degree are utilized herein to represent the inherent degree of uncertainty that may be attributed to any quantitative comparison, value, measurement, and/or other representation. The terms of degree may also be utilized herein to represent the degree by which a quantitative representation may vary (e.g., +10%) from a stated reference without resulting in a change in the basic function of the subject matter at issue.

For a better understanding of the present teachings, together with other and further objects thereof, reference is made to the accompanying drawings and detailed description and its scope will be pointed out in the detailed description and drawings.

Although these teachings have been described with respect to various embodiments, it should be realized these teachings are also capable of a wide variety of further and other embodiments within the spirit and scope of the appended claims.

What is claimed:

1. A quantum computing apparatus comprising:
a first layer of superconductor material;
a not intentionally doped metal-polar Group III nitride nucleation layer disposed over at least a portion of the layer of superconductor material;
a Group III nitride buffer layer epitaxially deposited on at least a portion of the not intentionally doped metal-polar Group III nitride nucleation layer;
a first Group III nitride layer epitaxially deposited on at least a portion of the Group III nitride buffer layer; and,
a second Group III nitride layer epitaxially deposited on the first Group III nitride layer; materials and thickness of the first Group III nitride layer and the second Group III nitride layer selected such that an electronic polarization discontinuity across a heterojunction between the first Group III nitride layer and the second Group III nitride layer causes formation of a 2D electron gas (2DEG) below the second Group III nitride layer.

2. The quantum computing apparatus of claim 1 further comprising:
a second layer of superconductor material epitaxially deposited on one surface of a substrate;
a layer of insulating or semiconducting or metallic material epitaxially deposited on the second layer of superconductor material;
the first layer of superconductor material being epitaxially deposited on said layer of insulating or semiconducting or metallic material; and
the second layer of superconductor material, the layer of insulating or semiconducting or metallic material and the first layer of superconductor material being patterned in order to obtain a plurality of quantum processing elements arranged in a matrix.

3. The quantum computing apparatus of claim 2 wherein at least a portion of the Group III nitride buffer layer comprises a not intentionally doped AlN layer, and wherein the quantum computing apparatus further comprises a first electrically conductive layer disposed on another surface of a portion of the not intentionally doped AlN layer;
the not intentionally doped AlN layer, the first electrically conductive layer and said layer of superconductor material constituting a BAW filter.

4. The quantum computing apparatus of claim 2 wherein the first Group III nitride layer and the Group III nitride buffer layer are a same Group III nitride material.

5. The quantum computing apparatus of claim 2 further comprising:
a structure comprising a portion of the Group III nitride buffer layer, a portion of the first Group III nitride layer, and a portion of the second Group III nitride layer;
an n-doped third Group III nitride material drain region recessed into at least the first Group III nitride layer, the n-doped third Group III nitride material drain region extending from a first end of the structure to less than half a distance from the first end of the structure to a second end of the structure;
an n-doped third Group III nitride material source region recessed into at least the first Group III nitride layer; the n-doped third Group III nitride material drain region extending from the second end of the structure to more than half a distance from the first end of the structure to a second end of the structure; the first Group III nitride layer being between the n-doped third Group III nitride material drain region and the n-doped third Group III nitride material source region and forming a channel layer; and
a gate electrode disposed above the second Group III nitride layer and between and not in contact with the n-doped third Group III nitride material source region and n-doped third Group III nitride material drain region.

6. The quantum computing apparatus of claim 5 wherein the structure also comprises a fourth Group III-N material passivation layer grown on second Group III nitride layer.

7. The quantum computing apparatus of claim 5 wherein the gate electrode includes a neck portion, the neck portion having a first width, and second portion, disposed on the first portion, and having an average width larger than the first width.

8. The quantum computing apparatus of claim 5 wherein the first Group III nitride material is GaN, the second Group III nitride material is AlN, and the third Group III nitride material is GaN.

9. The quantum computing apparatus of claim 6 wherein a first Group III nitride layer material is GaN, a second Group III nitride layer material is AlN, a third Group III nitride material is GaN, and a fourth Group III nitride material is GaN.

10. The quantum computing apparatus of claim 2 further comprising:
over another portion of the Group III nitride buffer layer, a third Group III nitride material layer epitaxially grown on the Group III nitride buffer layer;
wherein a difference between a normal component of a polarization of the third Group III nitride material layer and the Group III nitride buffer layer is negative; and wherein there is an energy band offset between valence bands of the Group III nitride buffer layer and the third Group III nitride material layer; an energy bandgap of a third Group III nitride material being smaller than an energy bandgap of Group II nitride material of the Group III nitride buffer layer; and
a 2D hole gas at a heterojunction between the Group III nitride buffer layer and the third Group III nitride material layer.

11. The quantum computing apparatus of claim 2 further comprising:
electrically conductive material filled through substrate vias (TSVs) connecting said one surface of the substrate; and
electronic components deposited on an opposing surface of the substrate.

12. The quantum computing apparatus of claim 11 wherein the electronic components comprise at least one a traveling wave parametric amplifier, or a transmission line.

13. A quantum computing apparatus comprising:
a substrate layer;
a first layer of superconductor material epitaxially deposited on one surface of the substrate layer or on a surface of a buffer layer disposed on the substrate layer;
a layer of insulating or semiconducting or metallic material epitaxially grown on the first layer of superconductor material;
a second layer of superconductor material grown on the layer of insulating or semiconducting or metallic material;
the first layer of superconductor material, the layer of insulating or semiconducting or metallic material and the second layer of superconductor material being patterned in order to obtain a plurality of quantum processing elements;
electrically conductive material filled through substrate vias (TSVs) connecting said one surface of the substrate layer or a surface of the buffer layer to an opposing surface of the substrate layer; and
electronic components deposited on the opposing surface of the substrate layer or on a third layer of superconductor material epitaxially disposed on the opposing surface of the substrate layer.

14. The quantum computing apparatus of claim 13 further comprising:
a first insulating material deposited over the first layer of superconductor material, the layer of insulating or semiconducting or metallic material, and the second layer of superconductor material and said one surface of the substrate layer; and
a second insulating material deposited over the electronic components and the opposing surface of the substrate layer.

15. The quantum computing apparatus of claim 13 wherein the electronic components comprise:
a metal-polar Group III nitride buffer layer epitaxially deposited on the opposing surface of the substrate layer;
a first Group III nitride layer epitaxially deposited on at least a portion of the metal-polar Group III nitride buffer layer; and
a second Group III nitride layer epitaxially deposited on the first Group III nitride layer;
materials and thickness of the first Group III nitride layer and the second Group III nitride layer selected such that electronic polarization discontinuity across a heterojunction between the first Group III nitride layer and the second Group III nitride layer causes formation of a 2D electron gas (2DEG) below the second Group III nitride layer.

16. The quantum computing apparatus of claim 15 wherein the electronic components further comprise:
a structure comprising a portion of the metal-polar Group III nitride buffer layer, a portion of the first Group III nitride layer, and a portion of the second Group III nitride layer;
an n-doped third Group III nitride material drain region recessed into at least the first Group III nitride layer, the n-doped third Group III nitride material drain region extending from a first end of the structure to less than half a distance from the first end of the structure to a second end of the structure;
an n-doped third Group III nitride material source region recessed into at least the first Group III nitride layer; the n-doped third Group III nitride material drain region extending from the second end of the structure to more than half a distance from the first end of the structure to a second end of the structure; the first Group III nitride layer being between the n-doped third Group III nitride material drain region and the n-doped third Group III nitride material source region and forming a channel layer; and
a gate electrode disposed above the second Group III nitride layer and between and not in contact with the n-doped third Group III nitride material source region and n-doped third Group III nitride material drain region.

17. The quantum computing apparatus of claim 16 wherein the electronic components also comprise;
a fourth Group III nitride material passivation layer grown on second Group III nitride layer.

18. The quantum computing apparatus of claim 16 wherein the gate electrode includes a neck portion, the neck portion having a first width, and second portion, disposed on the first portion, and having an average width larger than the first width.

19. The quantum computing apparatus of claim 17 wherein the second Group III nitride material is GaN, a third Group III-N material is AlN, and the fourth Group III nitride material is GaN.

20. The quantum computing apparatus of claim 13 wherein the electronic components comprise:
an AlN layer epitaxially deposited on a surface of an electrically conductive material filled through substrate vis substantially coincident with the opposing surface of the substrate layer; and
an electrically conductive layer deposited on the AlN layer; the AlN layer, the electrically conductive layer and said electrically conductive material filled via constituting a SAW filter.

21. The quantum computing apparatus of claim 13 wherein the first layer of superconductor material is epitaxially deposited on the surface of one of one or more buffer layers; the one or more buffer layers being disposed on a layer of dielectric or semiconductor material with anisotropic heat transfer properties; the layer of dielectric or semiconductor material with anisotropic heat transfer properties being disposed on the substrate layer; an in plane thermal conductivity of the layer of dielectric or semiconductor material being larger than a cross plane thermal conductivity of the layer of dielectric or semiconductor material;
the electrically conductive material filled through substrate vias (TSVs) traverse through the one or more buffer layers, the layer of dielectric or semiconductor material with anisotropic heat transfer properties, and the substrate layer.

22. The quantum computing apparatus of claim 21 wherein said dielectric or semiconductor material is hexagonal Boron Nitride (h-BN).

23. The quantum computing apparatus of claim 21 wherein a third layer of superconductor material is epitaxially deposited on the opposing surface of the substrate layer.

24. The quantum computing apparatus of claim 13 wherein the substrate layer is a low microwave loss, low thermal conductivity substrate.

25. A quantum computing apparatus comprising;
a plurality of quantum dots, each quantum dot comprising one of
(a) a nanocolumn structure having a Group III nitride buffer layer,
a first Group III nitride layer epitaxially deposited on at least a portion of the Group III nitride buffer layer, and
a second Group III nitride layer epitaxially deposited on the first Group III nitride layer, materials and thickness of the first Group III nitride layer and the second Group III nitride layer selected such that electronic polarization discontinuity across a heterojunction between the first Group III nitride layer and the second Group III nitride layer causes formation of a 2D electron gas (2DEG) below the second Group III nitride layer, or
(b) a nanocolumn structure having a Group III nitride buffer layer, a self assembled Group III nitride quantum well, and a first Group III nitride layer epitaxially deposited on the self assembled Group III nitride quantum well and the Group III nitride buffer layer as a covering layer; and
at least one of a superconducting stripline, superconducting transmission line, superconducting waveguide, superconducting conductor coupled to at least one of the quantum dots.

26. The quantum computing apparatus of claim 25 further comprising electrically conductive components disposed on or near said each quantum dot.

27. The quantum computing apparatus of claim 25 further comprising a stack of Group III nitride layers including the Group III nitride buffer layer of said each quantum dot, forms a bottom electrode.

28. The quantum computing apparatus of claim 25 wherein said each quantum dot comprises a nanocolumn structure having a Group III nitride buffer layer, a self assembled Group III nitride quantum well, and a first Group III nitride layer epitaxially deposited on the self assembled Group III nitride quantum well and the Group III nitride buffer layer as a covering layer; for said each quantum dot, a first superconducting transmission line or superconducting waveguide provides photons to said each quantum dot, and a second superconducting transmission line or superconducting waveguide receiving photons from said each quantum dot.

29. The quantum computing apparatus of claim 2 further comprising:
a component structure comprising a portion of the Group III nitride buffer layer, a portion of the first Group III nitride layer, and a portion of the second Group III nitride layer;
an electrically conductive source component recessed into at least substantially in contact with the first Group III nitride layer, the electrically conductive source component extending from a first end of the structure to less than half a distance from the first end of the structure to a second end of the structure;
an electrically conductive drain component recessed into at least substantially in contact with the first Group III nitride layer; the electrically conductive drain component extending from the second end of the structure to more than half a distance from the first end of the structure to a second end of the structure; the second Group III nitride layer being between the electrically conductive source component and the electrically conductive drain component;
a dielectric layer deposited on the second Group III nitride layer;
an electrically conductive gate component disposed on a portion of the dielectric layer;
wherein a voltage is applied between the gate component and ground, the component structure exhibiting quantum Hall resistance.

30. The quantum computing apparatus of claim 29 wherein the component structure is electrically connected to one quantum processing element from the plurality of quantum processing elements.

31. A quantum computing apparatus comprising:
a substrate layer;
a first layer of superconductor material epitaxially deposited on one surface of the substrate layer;
a layer of insulating or semiconducting or metallic material epitaxially grown on the first layer of superconductor material;
a second layer of superconductor material grown on the layer of insulating or semiconducting or metallic material;
the first layer of superconductor material, the layer of insulating or semiconducting or metallic material and the second layer of superconductor material being patterned in order to obtain one or more quantum processing elements and one or more sections of the first layer of superconductor material;
a first layer of electrically conductive material deposited over a section of the one surface of the substrate layer;
a first not intentionally doped AlN layer deposited over the first layer of electrically conductive material;
a second layer of electrically conductive material deposited over the first not intentionally doped AlN layer, over a portion of one side of the first not intentionally doped AlN layer, and operatively connecting to one of the one or more quantum processing elements; the first not intentionally doped AlN layer, the first layer of electrically conductive material and the second layer of electrically conductive material forming a first BAW filter;
the substrate layer selected to propagate acoustic communication from the first BAW filter;
a third layer of electrically conductive material deposited over a section of an opposing surface of the substrate layer; and
a second not intentionally doped AlN layer deposited over the first layer of electrically conductive material;
a fourth layer of electrically conductive material deposited over the second not intentionally doped AlN layer, over a portion of one side of the second not intentionally doped AlN layer, and operatively connecting to electronic components; the second not intentionally doped AlN layer, the third layer of electrically conductive material and the fourth layer of electrically conductive material forming a second BAW filter;
the second BAW filter located at a position on the opposing surface of the substrate layer receiving acoustic communication from the first BAW filter.

32. The quantum computing apparatus of claim 31 wherein the electronic components comprise:
a third layer of superconductor material epitaxially deposited on the opposing surface of the substrate layer;
a second layer of insulating or semiconducting or metallic material epitaxially grown on the third layer of superconductor material;
a fourth layer of superconductor material grown on the layer of insulating or semiconducting or metallic material;
the third layer of superconductor material, the second layer of insulating or semiconducting or metallic material and the fourth layer of superconductor material being patterned in order to obtain one or more second quantum processing elements and one or more sections of the third layer of superconductor material.

33. A method for forming a quantum computing apparatus, the method comprising:
depositing superconducting layers and dielectric or semiconducting or metallic layers separating the superconducting layers by molecular beam epitaxy (MBE), a first superconducting layer being deposited on one surface of a substrate; and
depositing Group III nitride layers for electronic components by metal-organic chemical vapor deposition (MOCVD).

34. The method of claim 33 further comprising depositing a not intentionally doped metal-polar Group III nitride nucleation layer on portion of a last superconducting layer by MOCVD; and
depositing a first Group III nitride layer for electronic components on the not intentionally doped metal-polar Group III nitride nucleation layer by MOCVD.

35. The method of claim 34 further comprising patterning, under another portion of the last superconducting layer, the superconducting layers and the dielectric or semiconducting or metallic layers separating the superconducting layers in order to obtain a plurality of quantum processing elements arranged in a matrix.

36. The method of claim 35 further comprising:
patterning one or more vias through the substrate under said another portion of the last superconducting layer;
filling the one or more vias with electrically conductive material; and
providing electrical connection to other component disposed on an opposite surface of the substrate.

37. The method of claim 33 wherein the Group III nitride layers for electronic components are deposited on an opposing surface of the substrate; and
wherein the method further comprises:
patterning one or more vias through the substrate at locations selected to provide an electrical connection from each of the electronic components to one of the superconducting layers; and
filling the one or more vias with electrically conductive material.

38. The method of claim 37 further comprising patterning, under a portion of a last superconducting layer, the superconducting layers and the dielectric or semiconducting or metallic layers separating the superconducting layers in order to obtain a plurality of quantum processing elements arranged in a matrix.

39. The method of claim 38 further comprising:
depositing a first insulating material over the plurality of quantum processing elements arranged in a matrix and the one surface of substrate; and
depositing a second insulating material over the electronic components and the opposing surface of the substrate.
